(19) United States
(12) Patent Application Publication
(10) Pub. No.: US 2024/0030168 A1
(43) Pub. Date: Jan. 25, 2024

(54) WAFER-ON-WAFER PACKAGING WITH CONTINUOUS SEAL RING

(71) Applicant: Taiwan Semiconductor Manufacturing Company, Ltd., Hsinchu (TW)

(72) Inventors: Wei-Yu Chen, (US); Hua-Wei Tseng, (US); Li-Hsien Huang, (US); Yinlung Lu, (US); Jun He, (US)

(21) Appl. No.: 17/814,525

(22) Filed: Jul. 24, 2022

(51) Int. Cl. H01L 23/00; H01L 25/065; H01L 23/48

(52) U.S. Cl. CPC H01L 24/08; H01L 24/94; H01L 24/80; H01L 25/0657; H01L 23/481; H01L 2225/06524; H01L 2225/06593; H01L 2924/35121; H01L 2924/30205; H01L 2224/08145; H01L 2224/80908; H01L 2224/80896; H01L 2224/80895; H01L 2224/8011

(57) ABSTRACT

A package structure is provided. The package structure includes a bottom die and a top die. The bottom die includes: a first active region surrounded by a first seal ring region; a first seal ring region including a bottom seal ring; and a first bonding layer disposed on a front side of the bottom die. The top die includes: a second active region surrounded by a second seal ring region; a second seal ring region including a top seal ring; and a second bonding layer disposed on a front side of the top die. The bottom die and the top die are bonded through hybrid bonding between the first bonding layer and the second bonding layer at an interface therebetween such that the bottom seal ring and the top seal ring are vertically aligned and are operable to form a continuous seal ring.

### FIELD

Embodiments of the present disclosure relate generally to semiconductor packaging, and more particularly to wafer-on-wafer (WoW) packaging with continuous seal rings.

### BACKGROUND

In recent years, the semiconductor industry has experienced rapid growth due to continuous improvement in the integration density of a variety of electronic components (e.g., transistors, diodes, resistors, capacitors, etc.). For the most part, improvement in integration density has resulted from the iterative reduction of minimum feature size, which allows more components to be integrated into a given area.

These continuously scaled electronic components require smaller packages that occupy less area than previous packages. Exemplary types of packages include quad flat pack (QFP), pin grid array (PGA), ball grid array (BGA), flip chips (FC), three-dimensional integrated circuits (3D ICs), wafer-level packages (WLPs), and package on package (PoP) devices. However, there are quite a few challenges to be handled for the technologies of advanced packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a cross-sectional view of a portion of an example package structure in accordance with some embodiments.

FIG. 2 is a schematic diagram illustrating a cross-sectional view of an enlarged zone of the package structure shown in FIG. 1 in accordance with some embodiments.

FIG. 3 is a flowchart diagram illustrating an example method for fabricating a package structure in accordance with some embodiments.

FIGS. 4A-4D are schematic cross-sectional views of a package structure formed at various stages in accordance with some embodiments.

FIGS. 4E-4F are schematic top views of a package structure formed at various stages in accordance with some embodiments.

FIGS. 4G-4H are schematic cross-sectional views of a package structure formed at various stages in accordance with some embodiments.

FIG. 5 is a schematic diagram illustrating a cross-sectional view of a portion of an example package structure 500 in accordance with some embodiments.

FIG. 6 is a diagram illustrating a top view of an example DTC region shown in FIG. 5 in accordance with some embodiments.

FIG. 7 is a flowchart diagram illustrating an example method 700 in accordance with some embodiments.

FIG. 8 is a flowchart diagram illustrating an example method 800 in accordance with some embodiments.

FIG. 9A is a schematic diagram illustrating a cross-sectional view of a portion of an example package structure in accordance with some embodiments.

FIG. 9B is a schematic diagram illustrating a bottom view of a top die shown in FIG. 9A in accordance with some embodiments.

FIG. 9C is a schematic diagram illustrating a cross-sectional view taken at A-A′ shown in FIG. 9B in accordance with some embodiments.

FIG. 9D is a schematic diagram illustrating a cross-sectional view of a portion of a close variation of the example package structure of FIG. 9C in accordance with some embodiments.

FIG. 9E is a schematic diagram illustrating a bottom view of a top die in another example package structure in accordance with some embodiments.

FIG. 10 is a flowchart diagram illustrating an example method of monitoring the seal ring delamination using the DMS according to some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

Packaging technologies were once considered just back-end processes, almost an inconvenience. Times have changed. Computing workloads have evolved more over the past decade than perhaps the previous four decades. Cloud computing, big data analytics, artificial intelligence (AI), neural network training, AI inferencing, mobile computing on advanced smartphones, and even self-driving cars are all pushing the computing envelope. Modern workloads have brought packaging technologies to the forefront of innovation, and they are critical to a product's performance, function, and cost. These modern workloads have pushed the product design to embrace a more holistic approach for optimization at the system level.

Wafer-on-wafer (WoW) packaging is one of the trending packaging technologies. In wafer-on-wafer packaging, a first wafer is physically bonded to a second wafer, creating a wafer-on-wafer structure (WoW structure). The wafer-on-wafer structure includes a large number of duplicate semiconductor devices separated by scribe lines. Subsequent to processes such as wafer bumping and wafer probing, the wafer-on-wafer structure is divided, along the scribe lines, into individual die-on-die structures using singulation techniques such as mechanical sawing, laser dicing, and the like.

On the other hand, stacking dies or chiplets (i.e., modular dies), with multi-layers, multi-chip sizes, and multi-functions becomes popular. In one implementation, the stacking dies are bonded together using hybrid bonding (HB). Hybrid bonding is a process that stacks and bonds dies using both dielectric bonding layers and metal-to-metal interconnects in advanced packaging. Since no bumps like micro-bumps are used, hybrid bonding is regarded as a bumpless bonding technique. Hybrid bonding can provide improved integration density, faster speeds, and higher bandwidth. In addition to die-to-die bonding, hybrid bonding can also be used for wafer-to-wafer bonding and die-to-wafer bonding.

A semiconductor package structure (sometimes also referred to as a “package structure”) sometimes includes a bottom die and a top die. The bottom die has a first active region surrounded by a bottom seal ring, and the top die has a second active region surrounded by a top seal ring. The bottom die and the top die are bonded through hybrid bonding at an interface therebetween such that the first active region and the second active region are aligned and bonded.

There are, however, some challenges related to the above package structure. In particular, the top seal ring and the bottom seal ring are not bonded. Therefore, the seal ring in the package structure is discontinuous. Such a discontinuous seal ring may not produce high bonding strength between the top die and bottom die and thus has less structural stability. In addition, the discontinuous seal ring may be less protective against the intrusion of cracks, moisture, and chemical damages. The discontinuous seal ring may also become a weak point in the package structure for delamination propagation. Moreover, unwanted electrical charges are generated and accumulated in the package structure during the wafer stacking and bonding process. But there is a lack of effective and efficient means to discharge the unwanted charges. Further, there is also a lack of a quick and effective means to detect and monitor the delamination in the seal ring of the package structure.

In accordance with some aspects of the disclosure, novel package structures are provided. An example of the novel package structure includes a bottom die and a top die. The bottom die includes a first active region surrounded by the first seal ring region, a first seal ring region having a bottom seal ring, and a first bonding layer disposed on a front side of the bottom die. The top die includes a second active region surrounded by the second seal ring region, a second seal ring region having a top seal ring, and a second bonding layer disposed on a front side of the top die. The bottom die and the top die are bonded through hybrid bonding between the first bonding layer and the second bonding layer at an interface therebetween such that the first seal ring region and the second seal ring region are vertically aligned. Importantly, the bottom seal ring and the top seal ring can be vertically aligned and bonded to form a continuous seal ring in the package structure.

The continuous seal ring mechanically and electrically integrates the bottom seal ring of the bottom die and the top seal ring of the top die of the package structure. The continuous seal ring could advantageously strengthen the interfacial bonding force of the package structure, improve the structural stability, mitigate the risk of delamination, and enhance the protection of active devices in the active region. In addition, the continuous seal ring can be made in a cost-effective manner without an additional mask during the step of forming the hybrid bonding metal pads in the bonding layers.

In some embodiments, the novel package structure further includes deep trench capacitors (DTCs) and an additional active region. The additional active region provides an additional electrical path that enables the discharge of unwanted charges generated during the wafer bonding process, thereby protecting the DTCs and other active devices against damages caused by electrostatic overstress (EOS) or electrostatic discharge (ESD).

In some embodiments, the novel package structure further includes a delamination monitoring structure (DMS). The combination of DMS and the continuous seal ring enables fast and sensitive detection of delamination in the continuous seal ring of the entire package structure, which significantly improves the overall efficiency reliability test, as compared with the discontinuous seal ring.

### Example WoW Package Structure with Continuous Seal Ring(s)

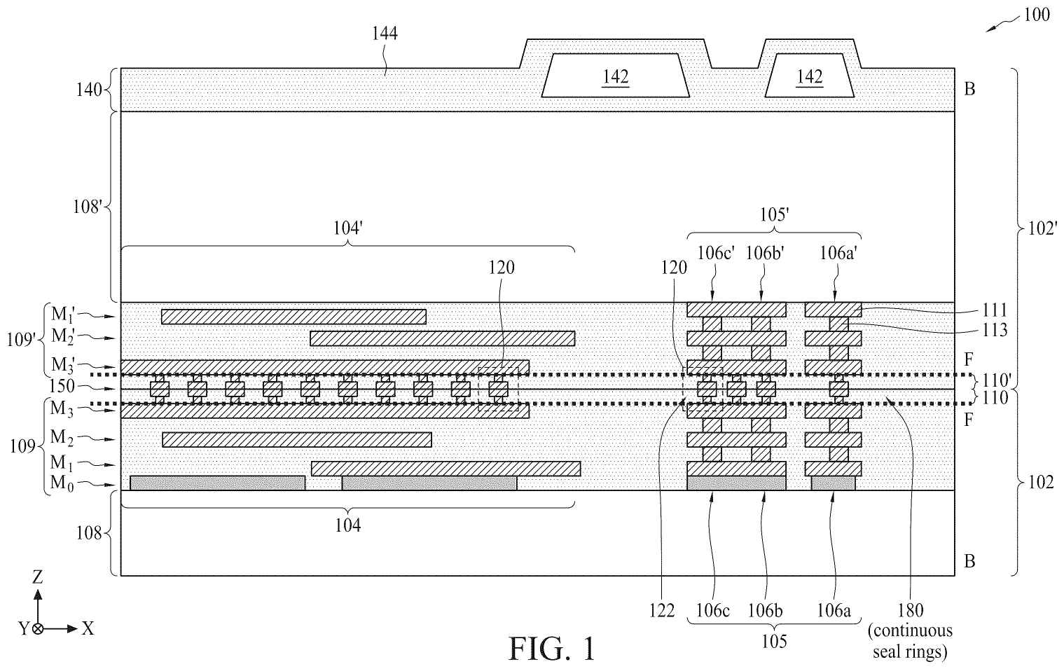

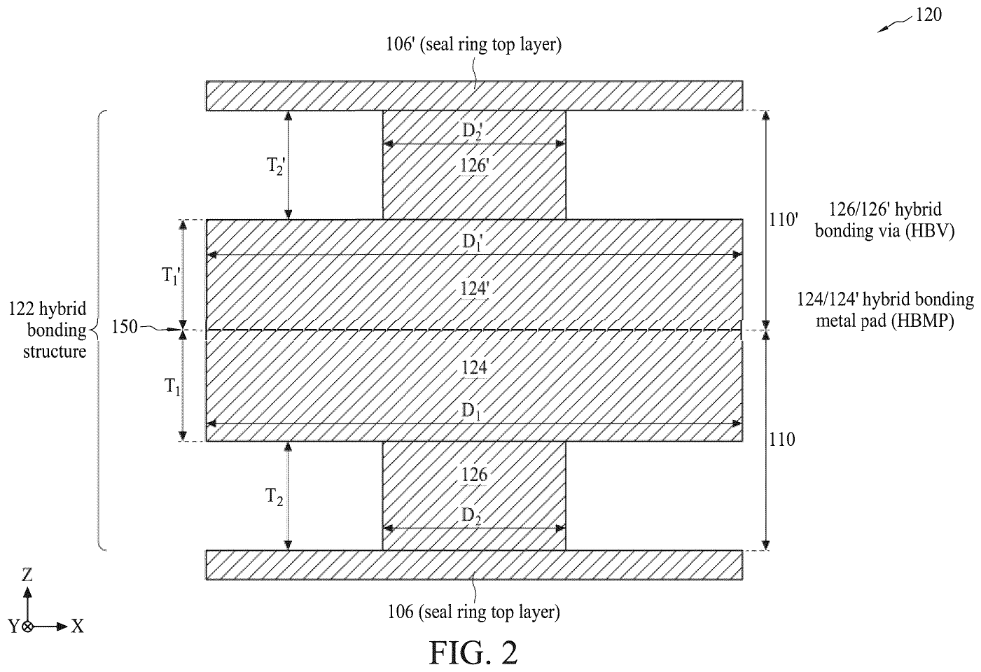

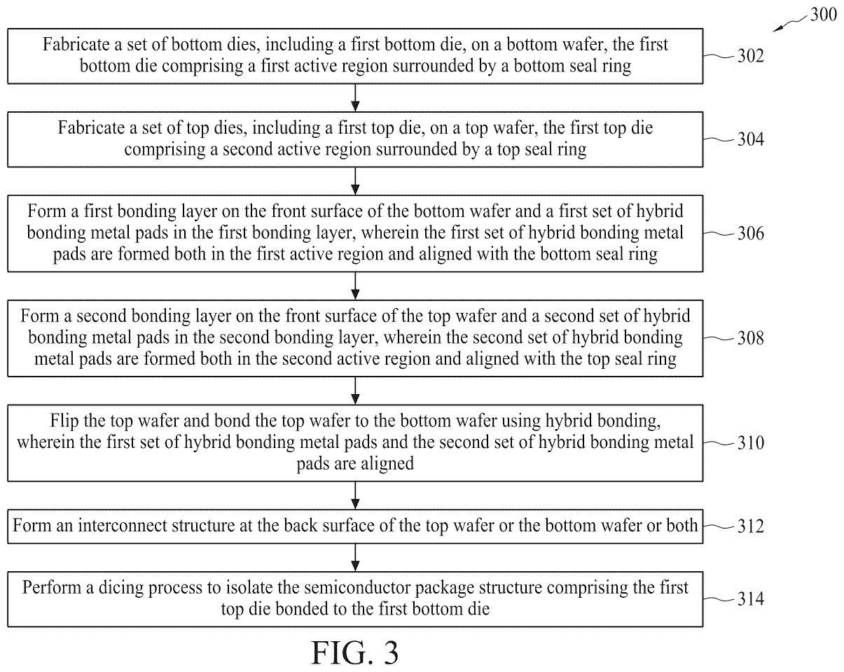

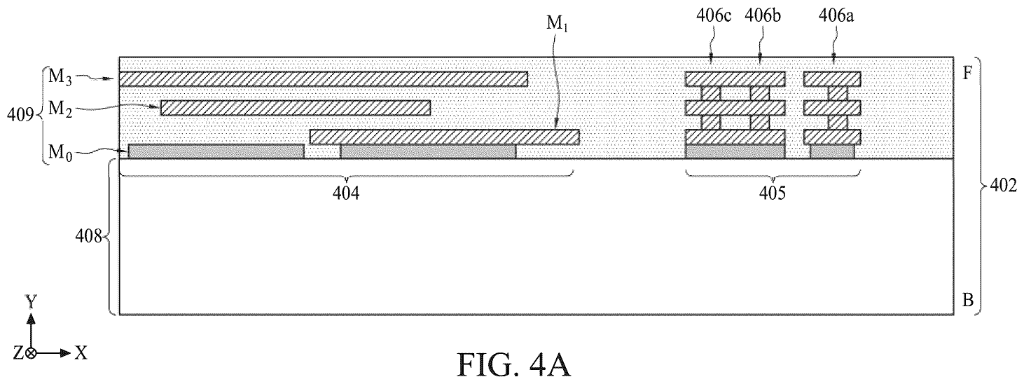

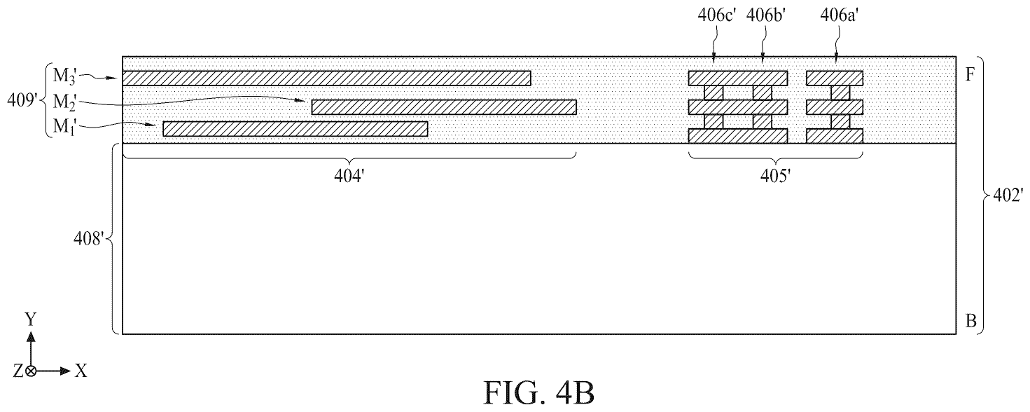

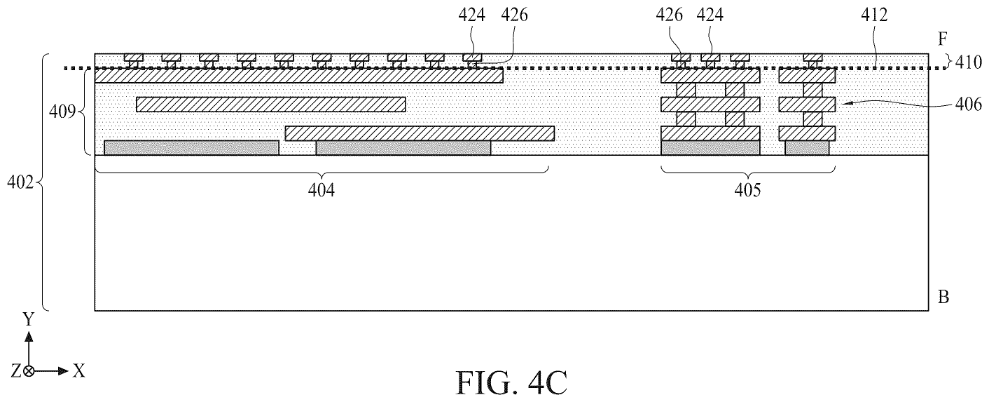

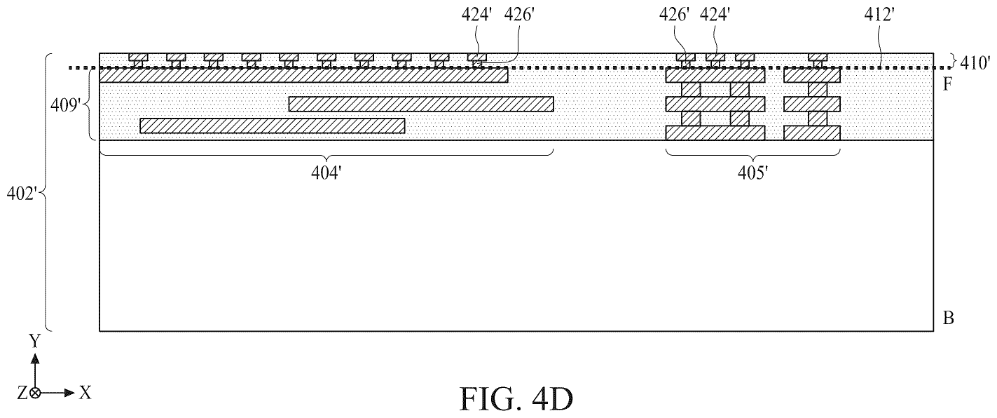

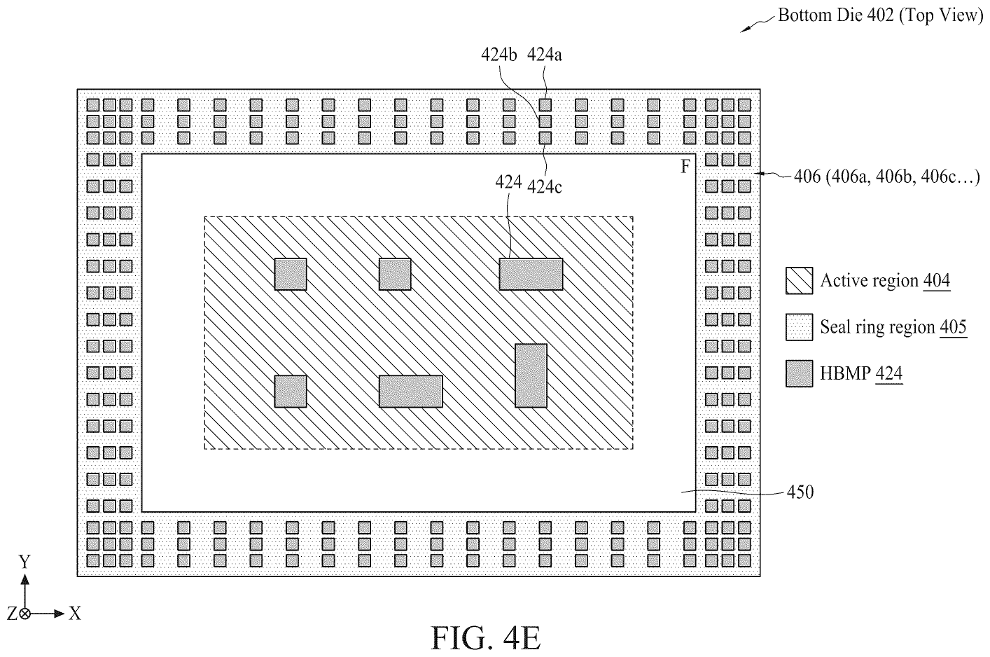

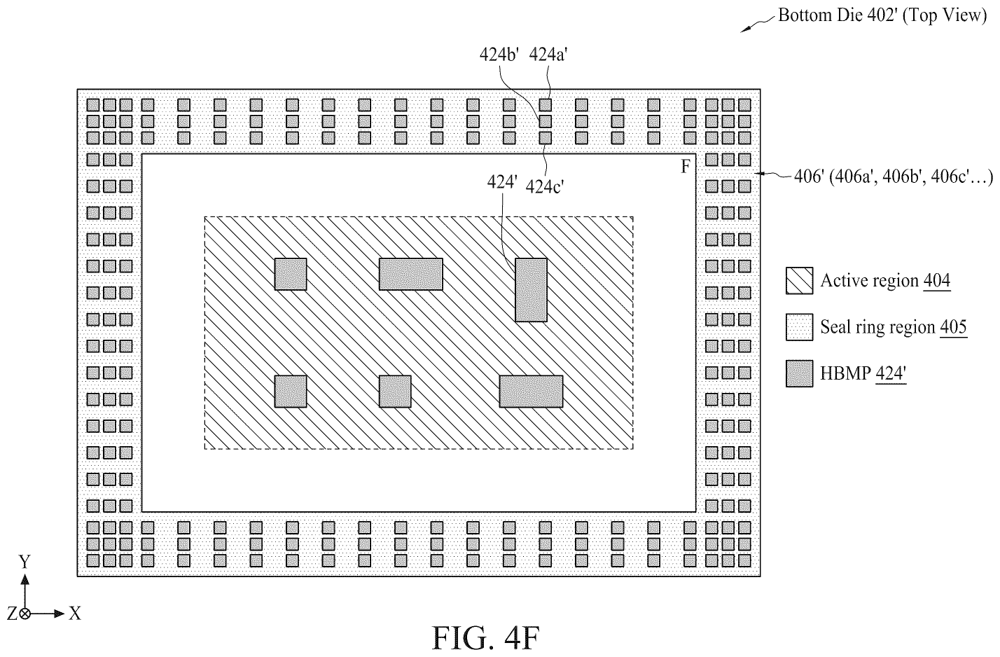

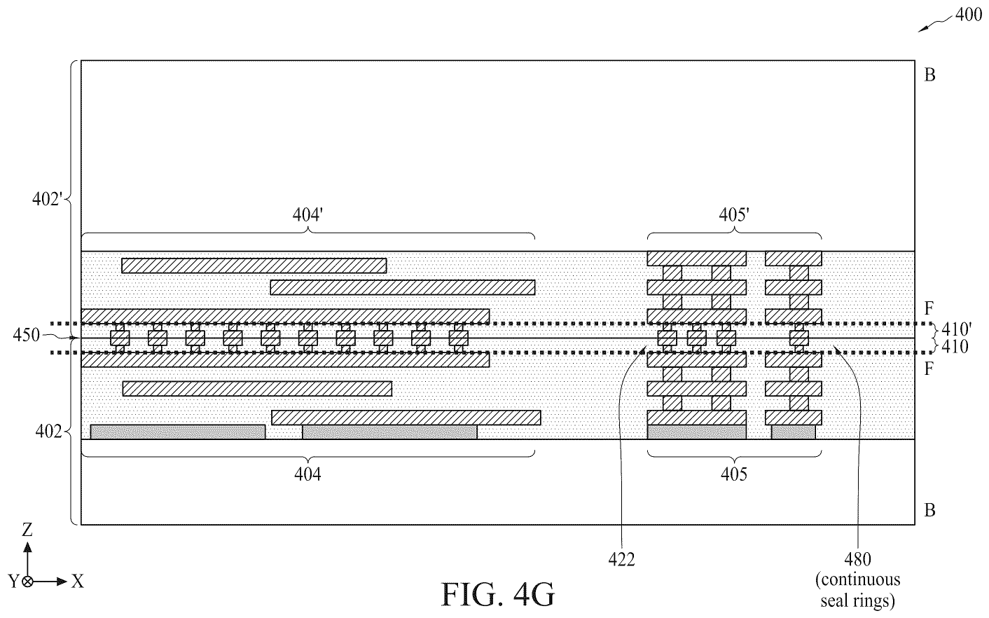

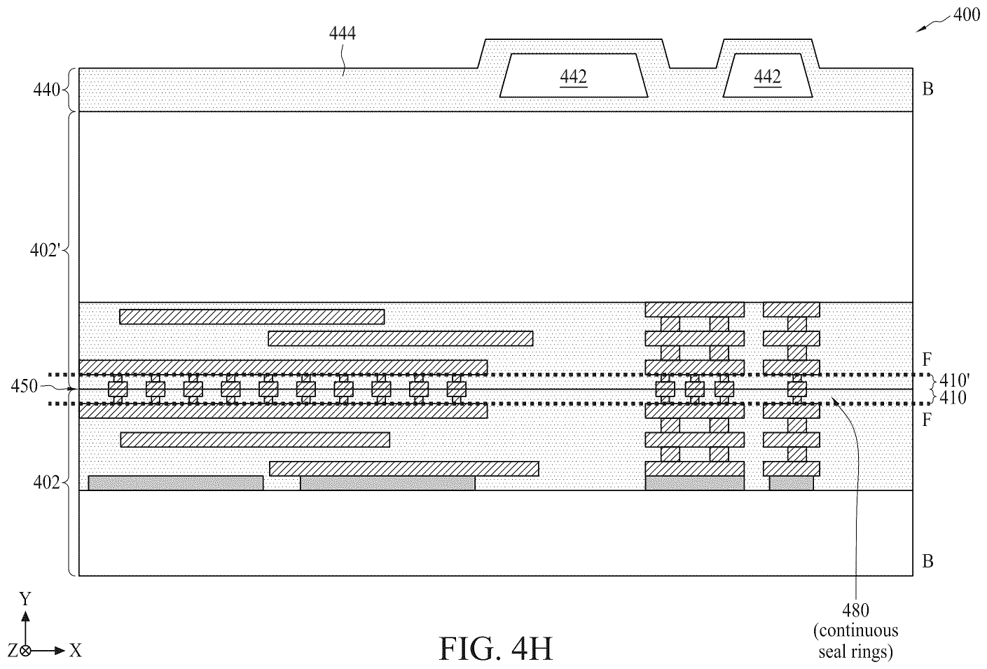

Now referring to FIGS. 1-3 and 4A-4G, examples of the package structure and method of making the same will be described. FIG. 1 is a schematic diagram illustrating a cross-sectional view of a portion of an example package structure 100 in accordance with some embodiments. FIG. 2 is a schematic diagram illustrating a cross-sectional view of the enlarged zone 120 of the package structure 100 shown in FIG. 1 in accordance with some embodiments. FIG. 3 is a flowchart diagram illustrating an example method 300 for fabricating a package structure in accordance with some embodiments. FIGS. 4A-4H are schematic cross-sectional views (FIGS. 4A-4D and 4G-4H) and top views (FIGS. 4E-4F) of a package structure formed at various stages in accordance with some embodiments. It should be understood that the illustrated package structure and various components thereof are exemplary rather than limiting. One of ordinary skill in the art would recognize many variations, modifications, and alternatives within the contemplation of the present disclosure. It should also be understood that FIGS. 1-2 and 4A-4G are not drawn to scale.

In the illustrated example, the package structure 100 includes a bottom die 102 and a top die 102′. The bottom die 102 has a front side (denoted as “F” in FIG. 1) and a back side (denoted as “B” in FIG. 1). Similarly, the top die 102′ has a front side (F) and a back side (B). In the example shown in FIG. 1, the top die 102′ has been flipped, i.e., upside down. In the package structure 100, the bottom die 102 and the top die 102′ are aligned in the Z-direction and bonded to each other through hybrid bonding at an interface 150 therebetween, with the front side of the top die 102′ facing the front side of the bottom die 102 in the Z-direction (denoted as “F-to-F bonding”). The bottom die 102 includes a bottom silicon substrate 108, and a first bonding layer 110 formed and disposed on the front surface of the bottom silicon substrate 108. In one implementation, the first bonding layer 110 is made of a dielectric and can be used for bonding with a second bonding layer 110′ disposed on the front surface of a top silicon substrate 108′ of the top die 102′.

One or more semiconductor devices (e.g., transistors, resistors, capacitors, inductors, etc.) are formed on the bottom silicon substrate 108 of the bottom die 102 and the top silicon substrate 108′ of the top die 102′, respectively, in a front-end-of-line (FEOL) process before the bottom die 102 and the top die 102′ are bonded.

A first multilayer interconnect (MLI) structure 109 is disposed over the one or more semiconductor devices of the bottom die 102, before hybrid bonding. The first MLI structure 109 includes a combination of dielectric layers and conductive layers configured to form various interconnect structures. The conductive layers are configured to form vertical interconnect features (e.g., device-level contacts, vias, etc.) and horizontal interconnect features (e.g., conductive lines extending in a horizontal plane). Vertical interconnect features typically connect horizontal interconnect features in different layers (e.g., a bottom metal layer often denoted as “M₀,” a first metal layer often denoted as “M₁,” and a third metal layer often denoted as “M₃,” and so on) of the MLI structure 109. Likewise, the top die 102′ includes a second MLI structure 109′ having horizontal interconnect features in different layers (e.g., M₁′, M₂′, M₃′) that are interconnected through vertical interconnect features.

In the example shown in FIG. 1, the bottom die 102 includes a first active region 104 and a first seal ring region 105. The first active region 104 is surrounded by the first seal ring region 105 in the X-Y plane, as shown in FIG. 4G. Likewise, the top die 102′ includes a second active region 104′ surrounded by a second seal ring region 105′ as shown in FIG. 4H. In some embodiments, the first and second active regions 104 and 104′ are vertically aligned in the Z-direction; the first and second seal ring regions 105 and 105′ are vertically aligned in the Z-direction.

The first seal ring region 105 of the bottom die 102 further includes at least one bottom seal ring 106. The bottom seal ring 106 is a metallization structure that is located between and separates the first active region 104 of the bottom die 102 and the peripheral regions (or edges) of the bottom die 102. The bottom seal ring 106 surrounds the first active region 104 in the X-Y plane and prevents the intrusion of cracks and moisture penetration or chemical damage like acid, alkaline containing or diffusion of contaminating species.

In the example of FIG. 1, the first seal ring region 105 includes three concentric bottom seal rings: a first bottom seal ring 106a in the outer part of the first seal ring region 105; a second bottom seal ring 106b in the middle part of the first seal ring region 105; and a third bottom seal ring 106c in the inner part of the first seal ring region 105. The bottom seal rings 106a, 106b, and 106c may have the same or different widths in the horizontal direction. In some embodiments, each bottom seal ring 106 includes multiple seal ring metal layers 111 extending in the horizontal direction and a multiple seal ring vias 113 extending in the vertical direction. The seal ring metal layers 111 are interconnected by the seal ring vias 113 in the Z-direction. It should be understood that the number of seal rings is not limited to that is shown in FIG. 1, which may be adjusted according to the requirement. For example, the number of seal rings in the first seal ring region 105 may be in a range from 1 to 10. In case there are multiple bottom seal rings 106 in the first seal ring region 105, the multiple bottom seal rings may be electrically connected to each other through seal ring interconnection structures (not shown).

The bottom seal ring(s) 106 may be formed by formation of the seal ring metal layer 111 and seal ring via 113. For example, openings corresponding to the seal ring metal layer 111 and seal ring via 113 may be formed. A seed layer (not shown) may then be deposited in the openings. A subsequent mask can be deposited over the seed layer and patterned to create openings according to the seal ring metal layer 111 and seal ring via 113. The seal ring metal layer 111 and seal ring via 113 can then be formed by depositing a metal material such as copper, titanium, the like, or a combination thereof, formed by a plating process, such as electroless plating, electroplating, or the like on the seed layer first deposited in the openings and continuing the plating until the seal ring metal layer 111 has reached a desired height. The resulting seal ring metal layer 111 may have a height of about 0.1 μm to about 2.8 μm, such as about 2.8 μm. Other heights may be used for the seal ring metal layer 111. The seal ring via 113 may be formed simultaneously with the seal ring metal layer 111. Following the formation of the bottom seal ring 106, the mask may be removed by a suitable process, such as by ashing, and the remaining seed layer stripped away.

Likewise, the second seal ring region 105′ of the top die 102′ may also include at least one top seal ring 106′. In the illustrated example of FIG. 1, the top die 102′ includes three concentric top seal rings 106a′, 106b′, and 106c′ disposed in the second seal ring region, which are respectively aligned with the bottom seal rings 106a, 106b, and 106c disposed in the first seal ring region 105 of the bottom die 102 in the Z-direction, after the bottom die 102 and the top die 102′ are bonded through hybrid bonding.

In the example shown in FIG. 1, the bottom die 102 and the top die 102′ are bonded through multiple hybrid bonding structures (HBSs) 122 formed in the first and second bonding layers 110 and 110′ and vertically across the interface 150. The HBSs 122 in the first and second active regions 104 and 104′ are configured to mechanically and electrically connect the first and second MLI structures 109 and 109′ in the respective active regions 104 and 104′. On the other hand, the HBSs 122 in the first and second seal ring regions 105 and 105′ are also configured to mechanically and electrically connect the bottom seal ring(s) 106 and the top seal ring(s) 106′ in the respective seal ring regions 105 and 105′. In one embodiment, the HBSs 122 in the first and second active regions 104 and 104′ and the HBSs 122 in the first and second seal ring regions 105 and 105′ are fabricated simultaneously using one mask. As such, no additional mask is needed to fabricate the HBSs 122 in the first and second seal ring regions 105 and 105′. In some embodiments, the package structure 100 includes multiple HBSs 122. The number of the HBS 122 is not limited to that shown in FIG. 1, which may be adjusted according to the requirement.

Now referring to FIG. 2, an enlarged schematic view of zone 120 of the package structure 100 shown in FIG. 1 is illustrated. The HBS 122 includes a pair of hybrid bonding metal pad (HBMP) 124 and HBMP 124′ bonded to each other. The bottom HBMP 124 is located in the first bonding layer 110 of the bottom die 102, and the top HBMP 124′ is located in the second bonding layer 110′ of the top die 102′. In each HBS 122, the corresponding bottom and top HBMPs 124 and 124′ are connected at the interface 150 and aligned in the Z-direction. In some embodiments, each HBS 122 further includes a bottom hybrid bonding via (HBV) 126 and a top HBV 126′ corresponding to the bottom HBV 126. The bottom HBV 126 is disposed in the first bonding layer 110 and mechanically and electrically connects the bottom HBMP 124 and a front surface of the bottom seal ring 106t (“t” stands for “top”) of the bottom die. Likewise, the top HBV 126′ is disposed in the second bonding layer 110′ and mechanically and electrically connects the top HBMP 124′ and a front surface of the top seal ring 106t′ of the top die 102′. The HBMP and HBV may have various sizes and shapes. The bottom HBMP 124 has a horizontal critical dimension in the X-Y plane (denoted as D₁) and a thickness (denoted as T₁). Similarly, the bottom HBV 126 has a horizontal critical dimension in the X-Y plane (denoted as D₂) and a thickness (denoted as T₂). Likewise, the top HBMP 124′ has a critical dimension in the X-Y plane (denoted as D₁′) and a thickness (denoted as T₁′); the top HBV 126′ has a critical dimension in the X-Y plane (denoted as 132′) and a thickness (denoted as T₂′).

In some embodiments, D₁ and D₁′ are each independently at least 1 μm. In some embodiments, D₂ and D₂′ are each independently at least 1 μm. In some embodiments, T₁ and T₁′ are each independently at least 1 μm. In some embodiments, T₂ and T₂′ are each independently at least 0.5 μm. In some embodiments, D₁ and D₂ are in accordance with the following relationship: D₁>D₂. In some embodiments, D₁′ and D₂′ are in accordance with the following relationship: D₁′>D₂′. In some embodiments, T₁ and T₂ are in accordance with the following relationship: T₁>T₂. In some embodiments, T₁′and T₂′ are in accordance with the following relationship: T₁′>T₂′. In some embodiments, the bottom HBMP 124 and the top HBMP 124′ may be the same or substantially the same in shape and dimension. For example, D₁ is about the same as D₁′, and T₁ is about the same as T₁′. In some embodiments, the bottom HBV 126 and the corresponding top HBV 126′ may be the same or substantially the same in shape and dimension. For example, D₂ is about the same as D₂′, and T₂ is about the same as T₂′.

It should be understood that the number, size, and shape of the HBMPs and HBVs are not limited by the example shown in FIGS. 1-2. In other examples, there may be multiple HBMPs (124 and 124′) and multiple HBVs 126 with small critical dimensions and pitches, thus achieving better interconnect density and performance (e.g., faster speeds, higher bandwidth, and the like).

As illustrated in FIGS. 1 and 2, the HBSs 122 mechanically and electrically connect the bottom seal rings 106 of the bottom die 102 and the top seal rings 106′ of the top die 102′, thereby forming continuous seal rings 180 in the package structure 100. The continuous seal ring design advantageously strengthens the interfacial bonding force of the package structure, improves the structural stability, and mitigates the risk of delamination. In addition, no additional mask is needed to fabricate the HBSs 122 in the first and second seal ring regions 105 and 105′, as explained above. Accordingly, the fabrication of the continuous seal rings 180 is cost-effective.

Referring back to FIG. 1, the package structure 100 further includes at least one interconnect structure 140 disposed on the bottom surface of the top silicon substrate 108′ of the top die 102′. In other examples, the package structure 100 may include at least one interconnect structure disposed on the bottom surface of the bottom silicon substrate 108 of the bottom die 102. The interconnect structure 140 is electrically connected to various active and/or passive devices in the first and second active regions 104 or 104′. The interconnect structure 140 may include redistribution layer (RDL) structures, such as an inter-layer dielectric (ILD) and/or inter-metal dielectric layers (IMD) and conductive features (e.g., metal traces and vias) formed in alternating layers over the bottom surfaces of the silicon substrates 108 or 108′ using any suitable method. In some embodiments, the interconnect structure 140 includes one or more conductive traces (e.g., aluminum traces) 142 and a passivation layer 144 that covers the conductive traces 142. The passivation layer 144 may include low-k dielectric materials having k values, for example, lower than about 4.0 or even 2.8. In some embodiments, the passivation layer 144 may include undoped silicate glass (USG), spin-on carbon, and the like. The interconnect structure 140 may each independently have a thickness in a range from about 0.1 μm to about 6 μm, such as about 4 μm. Other thicknesses may be used.

FIG. 3 is a flowchart illustrating an example method 300 for making a package structure in accordance with some embodiments. In the illustrated example, the method 300 includes operations 302, 304, 306, 308, 310, 312, and 314. Additional operations may be performed. Also, it should be understood that the sequence of the various operations discussed with reference to FIG. 3 is provided for illustrative purposes, and as such, other embodiments may utilize different sequences. For example, operation 306 can be performed between operations 302 and 304. These various sequences of operations are to be included within the scope of embodiments.

At operation 302, multiple bottom dies are fabricated on a bottom wafer. The multiple bottom dies include a first bottom die 402 (similar to the bottom die 102 of FIG. 1) having a first active region 404 surrounded by a first seal ring region 405 on a bottom silicon substrate 408, as shown in the example of FIG. 4A. In some embodiments, operation 302 further includes forming a first multilayer interconnect (MLI) structure 409 in the first active region 404 and forming at least one bottom seal ring 406 (e.g., a first bottom seal ring 406a, a second bottom seal ring 406b, and a third bottom seal ring 406c, as shown in FIG. 4A) in the first seal ring region 405. In some embodiments, the outer boundaries of the first seal ring 406a define the outer boundaries of first bottom die 402.

At operation 304, multiple top dies are fabricated on a top wafer. Similar to operation 302, the multiple top dies include a first top die 402′ (similar to the top die 102′ of FIG. 1) having a second active region 404′ surrounded by a second seal ring region 405′ on a top silicon substrate 408′, as shown in the example of FIG. 4B. In some embodiments, operation 304 further includes forming a second multilayer interconnect (MLI) structure 409′ within the second active region 404′ and forming at least one top seal ring 406′ (e.g., 406a′, 406b′, and 406c′) in the second seal ring region 405′. In some embodiments, the outer boundaries of the first top seal ring 406a′ define the outer boundaries of the first top die 402′.

At operation 306, a first bonding layer is formed on the front side of the bottom wafer. As shown in the example of FIG. 4C, a first bonding layer 410 is formed and disposed on a front surface 412 of the bottom die 402. In some embodiments, forming the first bonding layer 410 further includes forming a first set of HBMPs 424 in the first bonding layer 410. The first set of HBMPs 424 are formed both in the first active region 404 and the first seal ring region 405. The first set of HBMPs 424 are horizontally aligned such that the front surfaces thereof are substantially coplanar in the X-Y plane. In some embodiments, forming the first bonding layer 410 further includes forming a first set of HBVs 426 in the first bonding layer 410. Each HBV 426 located in the first active region 404 may mechanically and electrically connect the corresponding HBMP 424 and the first MLI structure 409. Likewise, each HBV 426 located in the first seal ring region 405 may mechanically and electrically connect the corresponding HBMP 424 and the underlying bottom seal ring(s) 406 (e.g., 406a, 406b, and 406c).

At operation 308, a second bonding layer is formed on the front side of the top wafer. Similar to operation 306, a second bonding layer 410′ is formed and disposed on a front surface 412′ of the top die 402′, as shown in the example of FIG. 4D. In some embodiments, forming the second bonding layer 410′ further includes forming a second set of HBMPs 424′ in the second bonding layer 410′. The second set of HBMPs 424′ are formed both in the second active region 404′ and the second seal ring region 405′. The second set of HBMPs 424′ are horizontally aligned such that the front surfaces thereof are substantially coplanar in the X-Y plane. In some embodiments, forming the second bonding layer 410′ further includes forming a second set of HBVs 426′ in the second bonding layer 410′. Each HBV 426′ located in the second active region 404′ may mechanically and electrically connect the corresponding HBMP 424′ and the second MLI structure 409′. Likewise, each HBV 426′ located in the second seal ring region 105′ may mechanically and electrically connect the corresponding HBMP 424′ and the top seal ring(s) 406′ (e.g., 406a′, 406b′, 406c′, etc.).

FIG. 4E is a schematic diagram illustrating a top view of the bottom die 402 in accordance with some embodiments. As illustrated, the first active region 404 is surrounded by the first seal ring region 405. The first seal ring region 405 includes three concentric bottom seal rings 406a, 406b, and 406c. Both the first active region 404 and the first seal ring region 405 include multiple HBMPs 424 (including 424a, 424b, and 424c) having front surfaces that are coplanar at the interface 450. As illustrated, the HBMPs 424a, 424b, and 424c are respectively aligned to the bottom seal rings 406a, 406b, and 406c in the Z-direction.

FIG. 4F is a schematic diagram illustrating a top view of the top die 402′ in accordance with some embodiments. Similar to the bottom die 402 shown in FIG. 4E, the second active region 404′ of the top die 402′ is surrounded by the second seal ring region 405′. The second seal ring region 405′ includes three concentric top seal rings 406a′, 406b′, and 406c′. Both the second active region 404′ and the second seal ring region 405′ include multiple HBMPs 424′ (including 424a′, 424b′, and 424c′) having front surfaces that are coplanar at the interface 450. As illustrated, the HBMPs 424a′, 424b′, and 424c′ are respectively aligned to the top seal rings 406a′, 406b′, and 406c′ in the Z-direction. As will be explained below, the pattern of the HBMPs 424 in FIG. 4E corresponds to the pattern of the HBMPs 424′ in FIG. 4F. Specifically, the HBMP patterns can be regarded as mirror images with respect to the interface 450.

At operation 310, the top wafer is flipped and bonded to the bottom wafer using hybrid bonding. As shown in the example of FIG. 4G, the bottom die 402 and the flipped top die 402′ are bonded in the manner of “front-to-front” (i.e., “F-to-F”) bonding with the respective bonding layers 410 and 410′ connected at the interface 450 to form the package structure 400. In some embodiments, the first active region 404 of the bottom die 402 and the second active region 404′ of the flipped top die 402′ are aligned in the Z-direction, and the first seal ring region 405 of the bottom die 402 and the second seal ring region 405′ of the flipped top die 402′ are similarly aligned in the Z-direction during and after hybrid bonding. In some implementations, the first set of HBMPs 424 and the second set of HBMPs are correspondingly aligned in the X-Y plane and bonded at the interface 450, forming multiple HBSs 422. As illustrated, the front surfaces of the HBMPs 424 and the HBMP 424′ are bonded and coplanar at the interface 450 in both the active regions 404/404′ and the seal ring regions 405/405′. Similar to the HBSs 122 of FIGS. 1-2, the HBSs 422 in the seal ring regions 405/405′ mechanically and electrically connect the bottom seal rings 406 and the top seal rings 406′, thereby forming a continuous seal ring 480 in the package structure 400. The formed continuous seal rings 480 could improve the bonding strength and structural stability between the two dies 402 and 402′ in the resulted package structure 400.

At operation 312, an interconnect structure is formed over the back surface of the top wafer. As shown in the example of FIG. 4H, an interconnect structure 440 is formed and disposed over the back surface of the top silicon substrate 108′ of the top die 402′. The interconnect structure 440 is similar to the interconnect structure 140 of FIG. 1 and may include a conductive trace 442 and a passivation layer 444.

After the bottom wafer and the top wafer are bonded, a singulation (dicing) process is performed at operation 314 to isolate the structure shown in FIG. 4H into separate semiconductor package structures. In some embodiment, the singulation (dicing) process is a wafer dicing process or a wafer singulation process including mechanical sawing or laser cutting. So far, the package structure 400 is fabricated. The isolated package structure 400 has continuous seal rings 480 formed by the hybrid bonding of the top die 402′ and the bottom die 402.

### Example WoW Package Structure with Continuous Seal Ring(s) and Additional Active Region

The miniaturization of devices on modern integrated circuits resulted in challenges for circuit designers dealing with power delivery networks (PDNs, also known as power distribution networks). The use of FinFET devices increases the drive strength per unit area, requiring higher current densities and larger current transients. This trend has resulted in chips that are increasingly sensitive to fluctuating supply voltages, exacerbating the power integrity challenges of system design. Circuit designers rely on decoupling capacitors as a fundamental tool for reducing the impedance of PDNs and suppressing noise by decoupling or bypassing one part of a circuit from another. For signals, noise from the interconnect can be shunted through a decoupling capacitor before being passed to another circuit. However, decoupling capacitors are generally physically located in close proximity to the desired circuit in order to reduce parasitic resistances and inductances.

In some implementations, deep trench capacitors (DTCs) are embedded in the semiconductor package. DTCs are typically fabricated in a substrate (e.g., a silicon substrate), and a large number of DTCs form a DTC region. The DTC region can be considered as a bank of available DTC units, and any number of DTC units can form a capacitor with a capacitance proportional to the number of DTC units.

However, it has been discovered that a portion of DTC units in the DTC region are damaged in the wafer-on-wafer stacking process due to electrostatic overstress (EOS) or electrostatic discharge (ESD) that may occur when the top surfaces of the bottom wafer and the top wafer bonded together. Therefore, there is a need to address the DTC unit loss in the wafer-on-wafer stacking process.

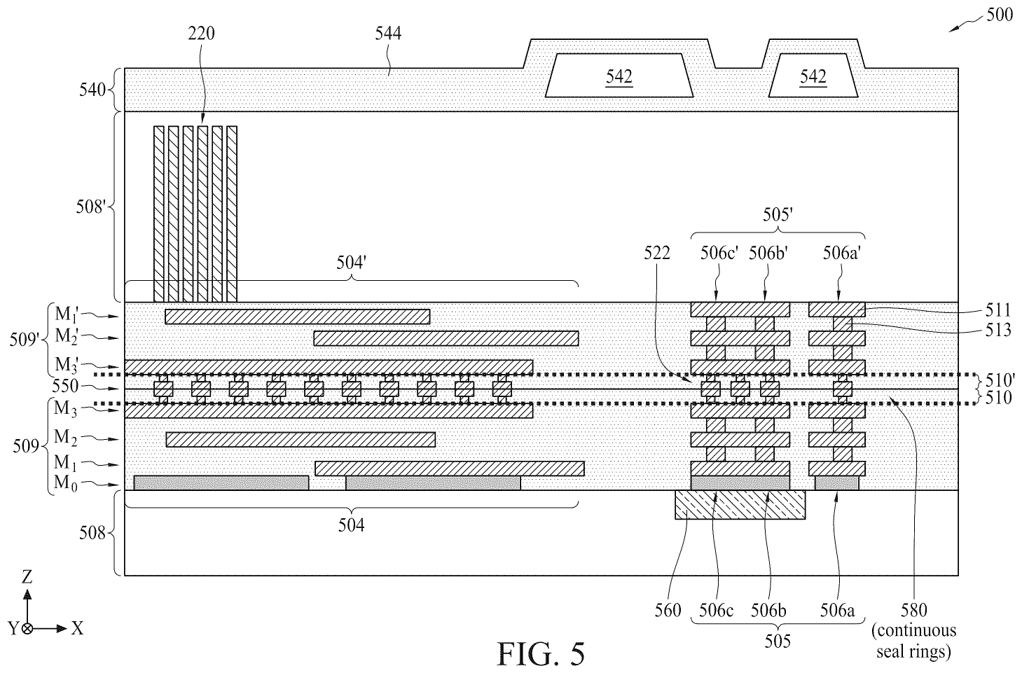

FIG. 5 is a schematic diagram illustrating a cross-sectional view of a portion of an example package structure 500 in accordance with some embodiments. The package structure 500 is similar to the package structure 100 shown in FIG. 1. The package structure 500 further includes a DTC region 220 and an additional active region 560. Various components of the package structure 500, e.g., the first and second bonding layers 510 and 510′, the first and second active regions 504 and 504′, the first and second seal ring regions 505 and 505′, the bottom seal rings 506 (e.g., 506a, 506b, and 506c), the top seal rings 506′ (e.g., 506a′, 506b′, and 506c′) , the bottom and top silicon substrates 508 and 508′, the MLI structures 509 and 509′, the seal ring metal layer 511, the seal ring via 513, the HBSs 522, the HBMPs 524 and 524′ (not shown), HBVs 526 and 526′ (not shown), the interconnect structure 540, the continuous seal ring 580, the one or more conductive traces 542, and the passivation layer 544 are identical or similar to their counterparts of the package structure 100 shown in FIGS. 1 and 2 and will not be repeated. In the example of FIG. 5, the DTC region 220 is embedded in the top silicon substrate 508′ of the top die 502′ and connected to the MLI structure 509′.

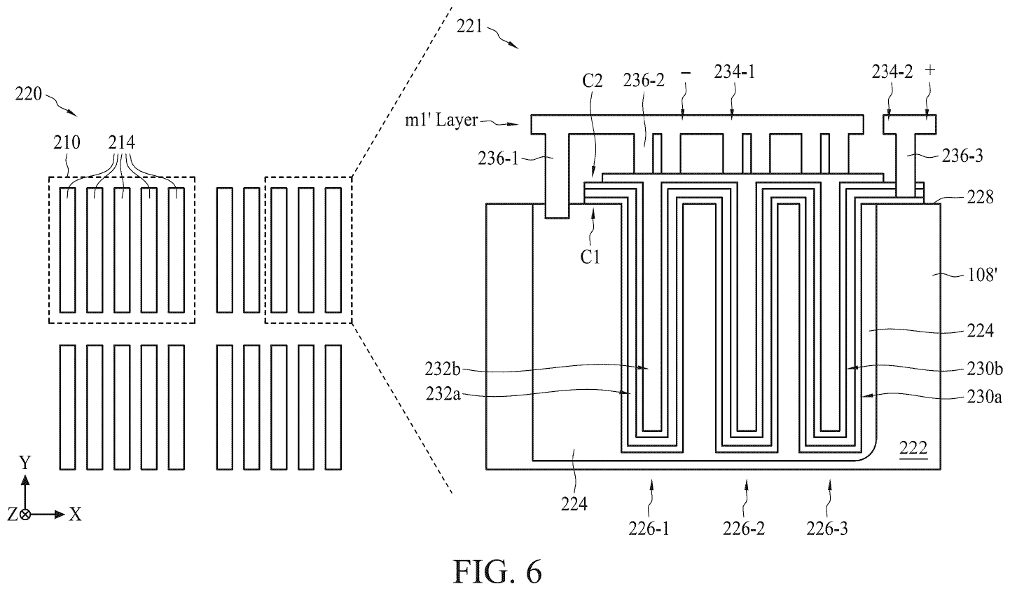

FIG. 6 is a diagram illustrating a top view of an example DTC region 220 in accordance with some embodiments. In the example shown in FIG. 6, the DTC region 220 includes an array of DTC unit cells 210 arranged in multiple rows and multiple columns extending in the X-Y plane. Each DTC unit cell 210 includes five DTC units 214 in this example. The five DTC units 214 in each DTC unit cell 210 are parallel to each other and extend in the Y-direction shown in FIG. 6. In some embodiments, the DTC units 214 are elongated.

It should be understood that the arrangement shown in FIG. 6 is exemplary, and one skilled in the art would appreciate other variations and modifications. For instance, instead of six DTC units 214 in one DTC unit cell 210, each DTC unit cell 210 may include three, four, six, or eight DTC units 214. In general, each DTC unit cell 210 may include a first number of DTC units 214, and the first number is an integer larger than one. In some embodiments, the first number is an integer equal to or larger than five.

A DTC unit 214 is a building block, each corresponding to a unit capacitance. All the DTC units 214 in the DTC region 220 are available to be combined to provide a target capacitance based on circuit design requirements. In other words, the DTC region 220 offers a bank of DTC units 214 that can be utilized flexibly.

In the example shown in FIG. 6, three DTC units 214 are connected in parallel to form a capacitor 221 (the cross-sectional view of the capacitor 221 is shown at the right side of FIG. 6). In the example shown in FIG. 6, the capacitor 221 is formed in the top silicon substrate 108′ shown in FIG. 5. In one embodiment, the top silicon substrate 108′ is doped and has a first conductivity type (e.g., n−). A conductive region 224, which often is highly doped and has a second conductivity type (e.g., p++) is formed within the substrate 222. Three trenches 226-1, 226-2, and 226-3, each corresponding to a DTC unit 214, extend downwardly from a substrate upper surface 228 into the conductive region 224. Alternatively, if the only required component of this integrated circuit is a capacitor that does not require capacitor-to-capacitor isolation (i.e., one plate of all capacitors can operate at the same potential), a heavily doped p++ or n++ wafer can be used to reduce the cost associated with the formation of the conductive region 224.

A first dielectric layer 230a is formed in the trenches 226-1, 226-2, and 226-3, and a first conductive layer 232a (e.g., a first polysilicon layer) is formed over the first dielectric layer 230a. A second dielectric layer 230b is formed in the trenches 226-1, 226-2, and 226-3 and over the first conductive layer 232a, and a second conductive layer 232b is formed in the trenches 226-1, 226-2, and 226-3 and over the second dielectric layer 230b. In one embodiment, the first dielectric layer 230a and the second dielectric layer 230b are made of a high-K dielectric with a high dielectric constant, as compared to silicon dioxide. In other words, the first dielectric layer 230a and the second dielectric layer 230b are high-K dielectric layers. In one embodiment, the first conductive layer 232a and the second conductive layer 232b are both polysilicon layers. In another embodiment, the first conductive layer 232a and the second conductive layer 232b are both metal layers (e.g., Ti layers).

The conductive region 224 is electrically connected to a metal track 234-1 in the ‘m₁” layer through a contact 236-1 (e.g., a via). The second conductive layer 232b is electrically connected to the metal track 234-1 through, for example, six contact structures 236-2 (e.g., vias). The first conductive layer 232a is electrically connected to a metal track 234-2 in the ‘m₁” layer through a contact 236-3 (e.g., a via).

As such, the metal tracks 234-1 and 234-2 and the contact structures 236-1, 236-2, and 236-3 couple a first capacitor C1 (which has the conductive region 224 and the first conductive layer 232a separated by the first dielectric layer 230a), in parallel with a second capacitor C2 (which has the first conductive layer 232a and the second conductive layer 232b separated by the second dielectric layer 230b). Thus, the DTC 210 can be regarded as two capacitors C1 and C2, which are “stacked” over one another and which are coupled in parallel to increase the capacitance density. In the example shown in FIG. 6, the metal track 234-2 is connected to a positive node through, for example, higher metal layers (e.g., the ‘m₂’ layer, the ‘m₃’ layer, etc.), while the metal track 234-1 is connected to a negative node through, for example, higher metal layers (e.g., the ‘m₂’ layer, the ‘m₃’ layer, the ‘m₄’ layer, the ‘m₅’ layer, etc.).

One skilled in the art should appreciate other variations and modifications of the example shown in FIG. 6. For instance, in another embodiment, trenches can be formed directly in the substrate without the conductive region, and two conductive layers and one dielectric layer sandwiched therebetween can be formed in the trenches, as compared to two conductive layers and two dielectric layers. Various designs and configurations can be employed depending on the design requirement and the application context.

Now referring back to FIG. 5, as explained above, a portion of DTC units 214 in the DTC region 220 may be damaged in the wafer-on-wafer stacking process due to electrostatic overstress (EOS) or electrostatic discharge (ESD). To address this issue, the additional active region 560 is introduced.

The additional active region 560 is embedded in the bottom silicon substrate 508 of the bottom die and electrically connected to the continuous seal rings 580 (bonded bottom seal ring 506 and top seal ring 506′ through hybrid bonding) in the first seal ring region 505. In the example of FIG. 5, the additional active region 560 is embedded in the bottom silicon substrate 508 and connected to the bottom seal rings 506b and 506c of the bottom die 502 at the front surface of the bottom silicon substrate 508. In some implementations, the additional active region 560 may be fabricated simultaneously when the first active region 504 of the bottom die is formed. Therefore, no additional mask is needed to fabricate the additional active region 560. Accordingly, the fabrication of the additional active region 560 is cost-effective.

The additional active region 560 advantageously provides an additional electrical path to discharge charges generated or accumulated at the interface 550 during the wafer-on-wafer stacking process, thereby mitigating the risk of damage caused by EOS or ESD. Accordingly, the additional active region 560 provides additional protection for the functional components in the first and second active regions 504 and 504′ as well as the DTC region 220.

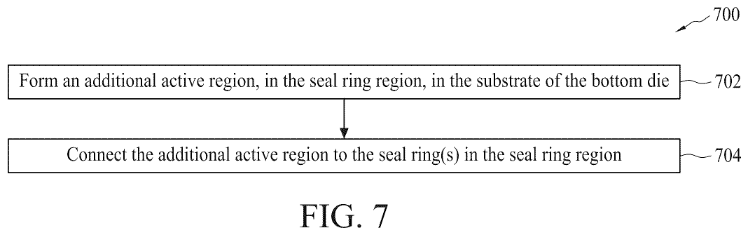

FIG. 7 is a flowchart diagram illustrating an example method 700 in accordance with some embodiments. In the illustrated example, a method 700 includes operations 702 and 704. At operation 702, an additional active region is formed in the seal ring region of a package structure that includes a bottom die and a top die bonded through hybrid bonding. At operation 704, the additional active region is connected to the continuous seal ring of the package structure. In some implementations, the additional active region is formed in the bottom wafer and connected to the continuous seal ring through, for example, the M₀ layer (i.e., the layer below the M₁ layer) in the seal ring region of the bottom die.

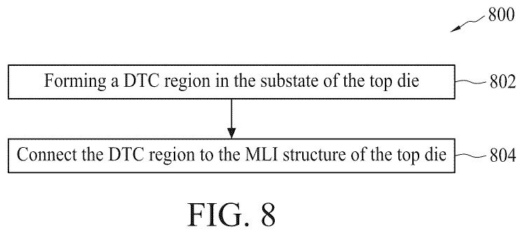

FIG. 8 is a flowchart diagram illustrating an example method 800 in accordance with some embodiments. In the illustrated example, a method 800 includes operations 802 and 804. At operation 802, a DTC region is formed in the substrate of the top die. At operation 804, the DTC region is connected to the MLI structure of the top die.

### Example WoW Package Structure with Continuous Seal Ring(s) and Delamination Monitoring Structures

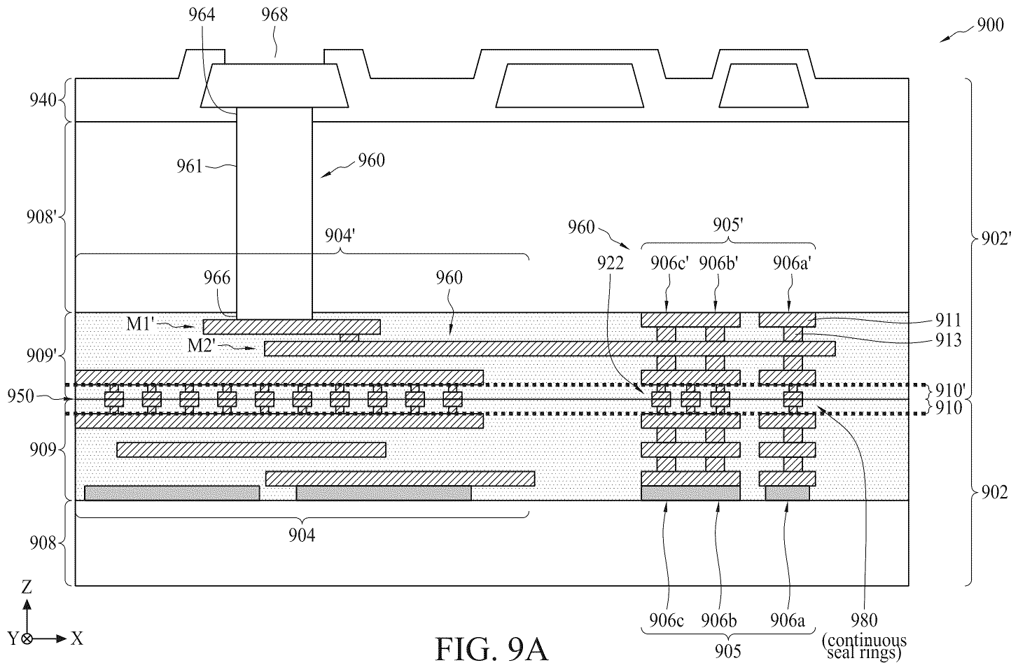

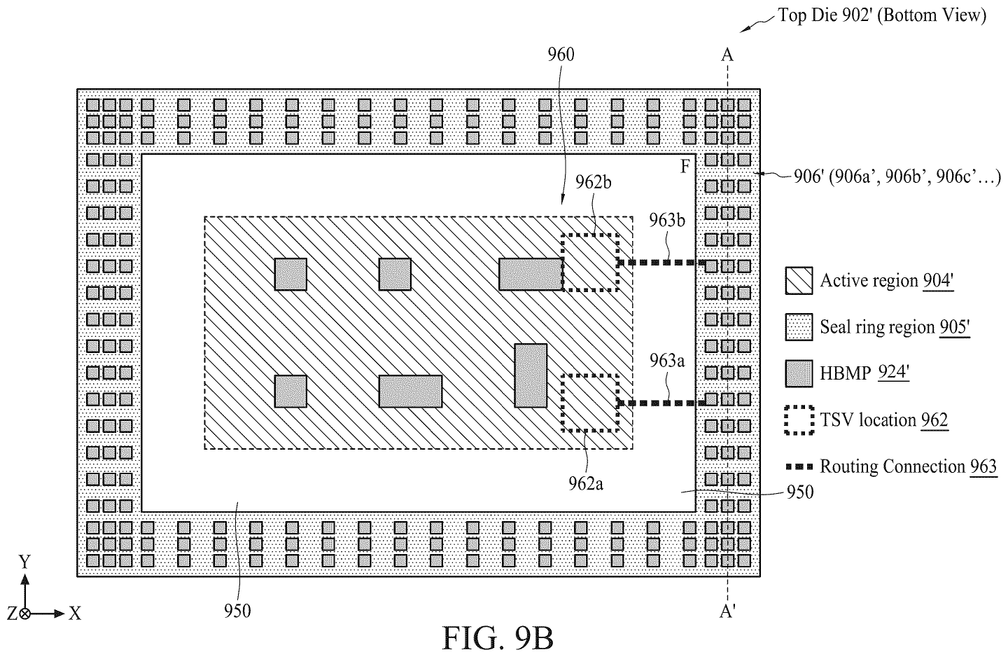

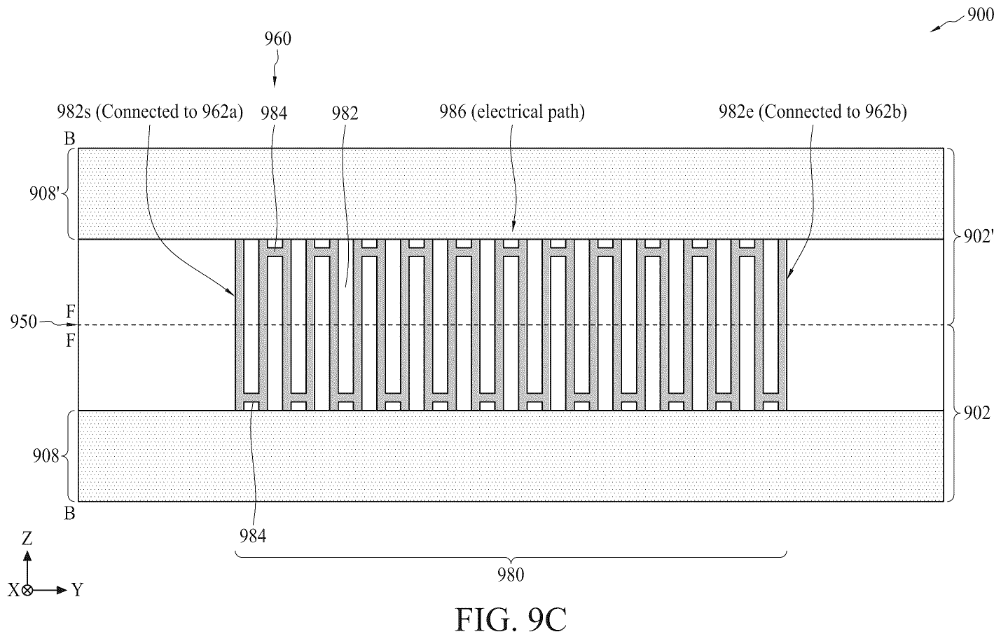

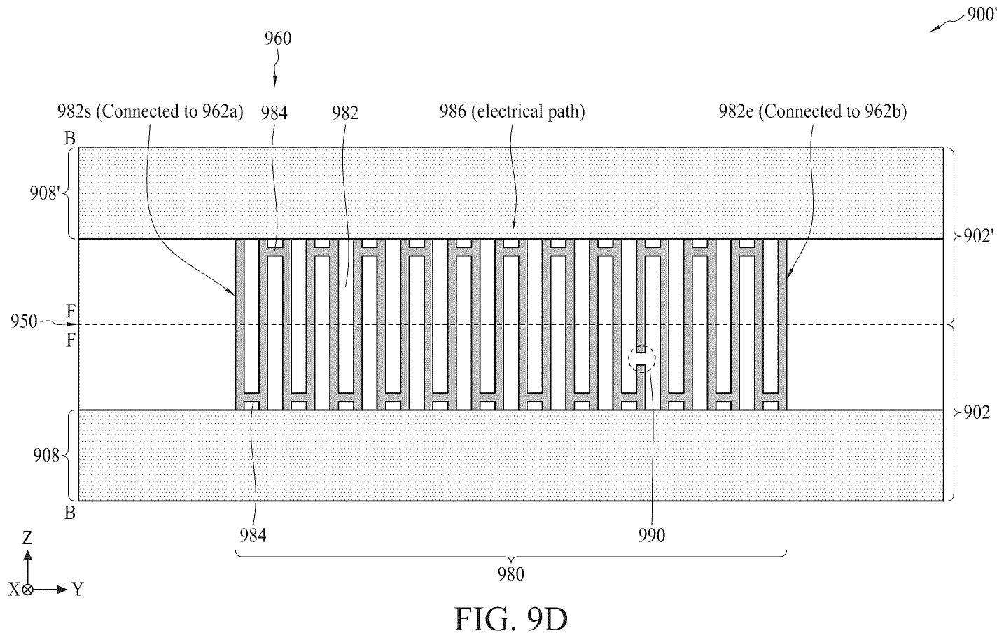

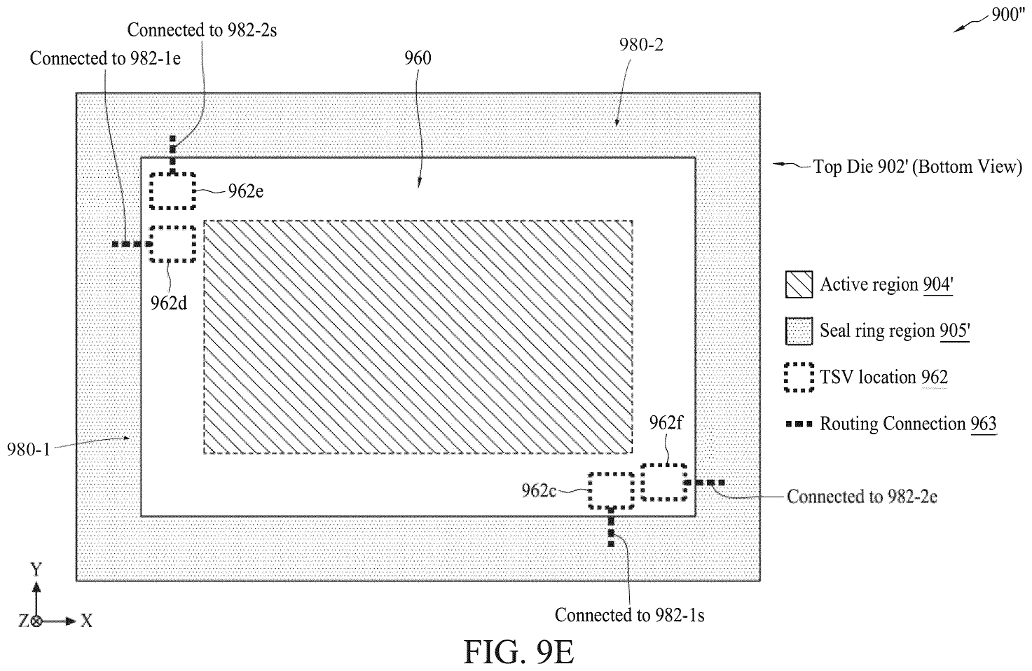

Now referring to FIGS. 9A-9E, example package structures with continuous seal ring(s) and delamination monitoring structure(s) will be illustrated and described. FIG. 9A is a schematic diagram illustrating a cross-sectional view in the X-Y plane of a portion of an example package structure 900 in accordance with some embodiments. FIG. 9B is a schematic diagram illustrating a bottom view of a top die 902′ in accordance with some embodiments. FIG. 9C is a schematic diagram illustrating a cross-sectional view taken at A-A′ shown in FIG. 9B in accordance with some embodiments. FIG. 9D is a schematic diagram illustrating a cross-sectional view in the Y-Z plane of a portion of a close variation of the example package structure 900 of FIG. 9C. FIG. 9E is a schematic diagram illustrating a bottom view of a top die 902′ of another package structure 900″ in accordance with some embodiments.

In the illustrated example of FIG. 9A, a package structure 900 is similar to the package structure 100 shown in FIG. 1. The package structure 900 includes a bottom die 902 and a top die 902′ bonded in the F-to-F bonding manner and further includes a delamination monitoring structure or disconnection monitoring structure (i.e., “DMS”, sometimes also referred to as “MS”) 960. Various components of the package structure 900, e.g., the first and second bonding layers 910 and 910′, the first and second active regions 904 and 904′, the first and second seal ring regions 905 and 905′, the bottom seal rings 906 (e.g., 906a, 906b, and 906c), the top seal rings 906′ (e.g., 906a′, 906b′, and 906c′), the bottom and top silicon substrates 908 and 908′, the first and second MLI 909 and 909′, the seal ring metal layer 911, the seal ring via 913, the HBSs 922, the HBMPs 924 and 924′ (not shown), the HBVs 926 and 926′ (not shown), the interconnect structure 940 are identical or similar to their counterparts of the package structure 100 shown in FIGS. 1-2 and will not be repeated.

The DMS 960 is configured to monitor the quality of the continuous seal ring(s) 980 (bonded bottom and top seal rings 906 and 906′ through hybrid bonding) and detect disconnection of the continuous seal rings 980 caused by, for example, delamination, defect, broken site, void, or the like. In some embodiments, the DMS 960 includes at least a pair of through-substrate vias (TSVs, sometimes also referred to as “through-silicon vias”) 961 and at least a pair of monitoring structure metal pads (MSMPs) 968 corresponding to the TSVs 961. The TSV 961 vertically penetrates the entire thickness of the top silicon substrate 908′ (of the top die 902′) in the Z-direction. The MSMPs 968 are each disposed over the back surface of the top silicon substrate 908′. The TSVs 961 each extend from a first end 964 to a second end 966. The first end 964 is mechanically and electrically connected to the corresponding MSMP 968; the second end 966 is mechanically and electrically connected to the MLI 909′ (e.g., the metal layer M₁′). The MSMPs 968 are exposed and allow to connect to an external device, e.g., a power source, which can apply a voltage bias between two MSMPs 968. As shown in FIG. 9A, the M₂′ layer of the second MLI structure 909′ extends from the second active region 904′ to the second seal ring region 905′ and electrically connects the second MLI structure 909′ and the three top seal rings 906c′, 906b′ and 906a′. As such, the TSV 961 is electrically connected to the top seal rings 906′s of the top die 902′.

It should be understood that although only one TSV 961 and only one MSMP 968 are shown in FIG. 9, at least one more TSV 961 and at least one more MSMP 968 exist at another cross-section not shown in FIG. 9A. In other embodiments, the TSVs 961 and MSMPs 968 may also be located on the bottom die 902. For example, the TSVs may penetrate the bottom silicon substrate 908 and connect the MLI 909 and the MSMP disposed on the back surface of the bottom silicon substrate 908. In some embodiments, the DMS 960 includes multiple TSVs 961 and MSMPs 968 located in both the bottom die 902 and the top die 902′.

FIG. 9B is a schematic diagram illustrating a bottom view of a top die 902′ in accordance with some embodiments. FIG. 9C is a schematic diagram illustrating a cross-sectional view taken at A-A′ shown in FIG. 9B in accordance with some embodiments. As illustrated, the DMS 960 includes a pair of TSVs 961 corresponding to a pair of TSV locations 962 (i.e., a first TSV location 962a and a second TSV location 962b), a first routing connection 963a and a second routing connection 963b (collectively as 963), and a portion of the continuous seal ring 980.

The portion of the continuous seal ring 980 includes multiple continuous seal ring pillars 982. In the example shown in FIG. 9C, the portion of the continuous seal ring 980 includes a starting continuous seal ring pillar 982s (“s” stands for “starting”), an ending continuous seal ring pillar 982e (“e” stands for “ending”), and at least one continuous seal ring pillar 982 between the starting continuous seal ring pillar 982s and the ending continuous seal ring pillar 982e along the Y-direction. Each of the continuous seal ring pillars (e.g., 982, 982s, and 982e) extends vertically from the front surface of the top silicon substrate 908′ to the front surface of the bottom silicon substrate 908 across the interface 950 in the Z-direction. Each continuous seal ring pillar may be composed of a portion of the ring metal layer 911 and a portion of the seal ring via 913 in the bottom and top seal rings 906 and 906′.

As illustrated, the portion of the continuous seal ring 980 further includes multiple seal ring pillar interconnections 984 disposed between two neighboring ones of the multiple continuous seal ring pillars 982 to form a continuous electrical path from the starting continuous seal ring pillar 982s to the ending continuous seal ring pillar 982e. In some embodiments, the seal ring pillar interconnections are metal tracks extending horizontally. In the example shown in FIG. 9C, a first portion of the continuous seal ring pillars 982 are located in the bottom die in proximity to the front surface of the bottom silicon substrate 908, and a second portion of the continuous seal ring pillars 982 are located in the top die in proximity to the front surface of the top silicon substrate 908′. As such, the electrical path 986 passes through almost the entire height in the Z-direction of each continuous seal ring pillar and crosses the interface 950 multiple times.

In the example shown in FIGS. 9B-9C, the first TSV 961 corresponding to the first TSV location 962a is electrically connected to the starting continuous seal ring pillar 982e through the first routing connection 963a; the second TSV 961 corresponding to the second TSV location 962b is electrically connected to the ending continuous seal ring pillar 982e through the second routing connection 963b. In some embodiments, the first routing connection 963a includes a first metal track disposed in the M₁′ layer in the top die 902′, and the second routing connection 963b includes a second metal track disposed in the M₁′ layer.

In some implementations, when a voltage bias is applied to the first TSV 961 corresponding to the first TSV location 962a and the second TSV 961 corresponding to the second TSV location 962b, e.g., through the corresponding MSMPs 968, an electrical current may be generated through the portion of the continuous seal ring 980.

During operation, the DMS 960 allows for monitoring the quality of the continuous seal ring 980 in the package structure 900. In one example, the DMS 960 could be used to detect if a disconnection 990 exists in the continuous seal ring 980 of the package structure 900, as shown in FIG. 9D. The disconnection 990 may include, among others, delamination inside the seal rings 906 and 906′, delamination in the bonding layer in proximity to the interface 950, broken site of the seal ring metal layers and the seal ring vias, void, or other types of disconnection of the continuous seal ring 980. It is important to note that the continuous seal ring formed through hybrid bonding according to the present disclosure advantageously allows for simultaneously detecting and monitoring the seal rings of both the top die 902′ and the bottom die 902 in the package structure 900, which significantly improves the efficiency of quality control and the overall reliability performance.

FIG. 9E shows another example package structure 900″, which is a variation of the package structure 900 shown in FIGS. 9A-9C. The package structure 900″ includes a DMS 960, which further includes at least two pairs of TSVs 961 (corresponding to the two pairs of TSV locations 962 shown in FIG. 9E). The first pair includes TSV locations 962c and 962d, and the second pair includes TSV locations 962e and 962f. The TSV locations 962 are located in the region between the second active region 904′ and the second seal ring region 905′. The two pairs of TSVs 961 corresponding to the two pairs of TSV locations 962 are respectively connected to two different portions of the continuous seal ring 980. For example, the first pair of TSVs 961 corresponding to the first pair of TSV locations 962c and 962d is connected to a first portion of the continuous seal ring 980-1 through the routing connections 963; the second pair of TSVs 961 corresponding to the TSV locations 962e and 962f is similarly connected to a second portion of the continuous seal ring 980-2 through the routing connections 963.

The first portion of the continuous seal ring 980-1 extends from a starting continuous ring pillar 982-1s to an ending continuous ring pillar 982-1e. Likewise, the second portion of the continuous seal ring 980-2 extends from a starting continuous ring pillar 982-2s to an ending continuous ring pillar 982-2e. As illustrated, the TSV 961 corresponding to the TSV location 962c is connected to the starting continuous ring pillar 982-1s; the TSV 961 corresponding to the TSV location 962d is connected to the ending continuous ring pillar 982-1e. Likewise, the TSV 961 corresponding to the TSV location 962e is connected to the starting continuous ring pillar 982-2s; the TSV 961 corresponding to the TSV location 962f is connected to the ending continuous ring pillar 982-2e.

During operation, the first pair of TSVs 961 corresponding to the first pair of TSV locations 962c and 962d allows for monitoring the delamination in the first portion of the continuous seal ring 980-1. Likewise, the second pair of TSVs 961 corresponding to the second pair of TSV locations 962e and 962f allows for monitoring the delamination in the second portion of the continuous seal ring 980-2.

It should be understood that the number of pairs of TSVs 961 is not limited to the example shown in FIG. 9E. In other examples, the package structure 900″ may include various numbers of the TSV pairs, on demand, to control the number, length, and location of the portion of the continuous seal ring 980 to be monitored.

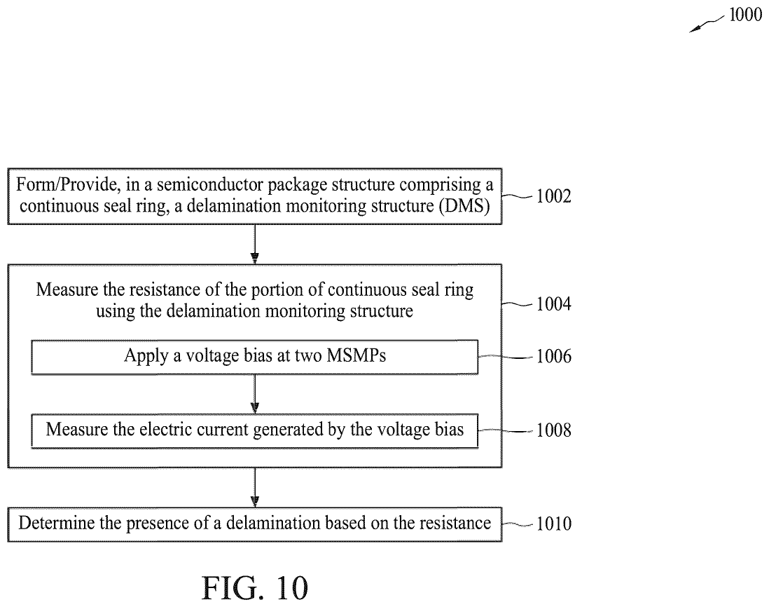

FIG. 10 is a flowchart diagram illustrating an example method 1000 of monitoring the seal ring delamination using the DMS according to some embodiments. In the illustrated example, the method 1000 includes operations 1002, 1004, and 1010.

At operation 1002, a DMS is provided in a package structure that includes a continuous seal ring, wherein the DMS includes two MSMPs, two TSVs corresponding to the two MSMPs, and at least a portion of the continuous seal ring connected to the two TSVs.

At operation 1004, the portion of the seal ring connected to the DMS is monitored using the DMS. In some implementations, operation 1004 can be implemented as operations 1006 and 1008. At operation 1006, a voltage bias is applied at the two MSMPs of the DMS. At operation 1008, the electric current generated by the voltage bias is measured.

At operation 1010, the presence of a disconnection (e.g., delamination or the like) is determined based on the resistance. As an example, in the package structure 900′ of FIG. 9D, if the portion of the continuous seal ring 980 has a disconnection 990, the resistance determined at operation 1010 would be significantly high (i.e., close to infinite). Thus, a disconnection in the monitored portion of the seal ring would be quickly and reliably determined based on the measured resistance.

### Various Combinations

A person having ordinary skills in the art should understand that the present disclosure is not limited to the examples shown in the FIGS. 1-10. Various combinations of the features disclosed herein may be combined, without limitation, in other embodiments. For example, a package structure according to the present disclosure may include a continuous seal ring (e.g., 180 shown in FIG. 1), a DTC region (e.g., 220 shown in FIG. 5), an additional active region (e.g., 560), and a DMS (e.g., 960 shown in FIG. 9A), in a feasible manner.

### Summary

In accordance with some aspects of the disclosure, a package structure is provided. The package structure includes a bottom die and a top die. The bottom die includes: a first active region surrounded by a first seal ring region; a first seal ring region including a bottom seal ring; and a first bonding layer disposed on a front side of the bottom die. The top die includes: a second active region surrounded by a second seal ring region; a second seal ring region including a top seal ring; and a second bonding layer disposed on a front side of the top die. The bottom die and the top die are bonded through hybrid bonding between the first bonding layer and the second bonding layer at an interface therebetween such that the bottom seal ring and the top seal ring are vertically aligned and are operable to form a continuous seal ring.

In accordance with some aspects of the disclosure, a method for fabricating a package structure is provided. The method includes fabricating a plurality of bottom dies, including a first bottom die, on a bottom wafer, the first bottom die include a first active region surrounded by a bottom seal ring; fabricating a plurality of top dies, including a first top die, on a top wafer, the first top die including a second active region surrounded by a top seal ring; forming a first bonding layer on a front surface of the bottom wafer and a first set of HBMPs in the first bonding layer, wherein the first set of HBMPs are formed both in the first active region and aligned with the bottom seal ring; forming a second bonding layer on a front surface of the top wafer and a second set of HBMPs in the second bonding layer, wherein the second set of HBMPs are formed both in the second active region and aligned with the top seal ring; flipping the top wafer and bonding the flipped top wafer to the bottom wafer using hybrid bonding, wherein the first set of HBMPs and the second set of HBMPs are aligned and connected at an interface therebetween; and performing a dicing process to isolate the package structure including the first top die bonded to the first bottom die.

In accordance with some aspects of the disclosure, a package structure is provided. The package structure includes a bottom die; a top die; and a delamination monitoring structure (DMS). The bottom die includes: a first active region surrounded by a first seal ring region; a first seal ring region including a bottom seal ring; a first bonding layer disposed on a front side of the bottom die; a first plurality of bottom HBMPs disposed in the first bonding layer in the first seal ring region; and a first plurality of bottom HBVs disposed in the first bonding layer and respectively connecting the bottom HBMPs and the bottom seal ring. The top die includes: a second active region surrounded by a second seal ring region; a second seal ring region including a top seal ring; and a second bonding layer disposed on a front side of the top die; a first plurality of top HBMPs disposed in the second bonding layer in the second seal ring region, wherein the first plurality of top HBMPs are bonded to the first plurality of the bottom HBMPs, respectively; and a first plurality top HBV disposed in the second bonding layer and respectively connecting the top HBMPs and the top seal ring. The bottom die and the top die are bonded through hybrid bonding between the first bonding layer and the second bonding layer at an interface therebetween such that the bottom seal ring and the top seal ring are vertically aligned. The bottom seal ring, the bottom HBV, the bottom HBMP, the top HBMP, the top HBV, and the top seal ring form a continuous seal ring. The DMS is configured to monitor delamination of the continuous seal ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure comprising:
a bottom die comprising:
a first active region surrounded by a first seal ring region;
a first seal ring region comprising a bottom seal ring; and
a first bonding layer disposed on a front side of the bottom die; and
a top die comprising:
a second active region surrounded by a second seal ring region;
a second seal ring region comprising a top seal ring; and
a second bonding layer disposed on a front side of the top die; and
wherein the bottom die and the top die are bonded through hybrid bonding between the first bonding layer and the second bonding layer at an interface therebetween such that the bottom seal ring and the top seal ring are vertically aligned and are operable to form a continuous seal ring.

2. The package structure of claim 1, further comprising:
a first plurality of bottom hybrid bonding metal pads (HBMPs) disposed in the first bonding layer in the first seal ring region; and
a first plurality of top HBMPs disposed in the second bonding layer in the second seal ring region, wherein the first plurality of top HBMPs are bonded to the first plurality of the bottom HBMPs, respectively.

3. The package structure of claim 2, further comprising:
a first plurality of bottom hybrid bonding vias (HBVs) disposed in the first bonding layer and respectively connecting the bottom HBMPs and the bottom seal ring; and
a first plurality of top HBVs disposed in the second bonding layer and respectively connecting the top HBMPs and the top seal ring.

4. The package structure of claim 1, wherein the first active region and the second active region are vertically aligned, and wherein the first seal ring region and the second seal ring region are vertically aligned.

5. The package structure of claim 4, further comprising:
a first multilayer interconnect (MLI) structure disposed in the first active region;
a second plurality of bottom hybrid bonding metal pads (HBMPs) disposed in the first bonding layer in the first active region and connected to the first MLI structure;
a second MLI structure disposed in the second active region; and
a second plurality of top HBMPs disposed in the second bonding layer in the second active region and connected to the second MLI structure, wherein the second plurality of top HBMPs are bonded to the second plurality of the bottom HBMPs, respectively.

6. The package structure of claim 1, further comprising an interconnect structure disposed on a bottom surface of the top die, wherein the interconnect structure comprises a conductive trace and a passivation layer that covers the conductive trace.

7. The package structure of claim 1, further comprising a (deep trench capacitor) DTC region embedded in the top die, the DTC region comprising an array of DTCs.

8. The package structure of claim 7, further comprising an additional active region embedded in the bottom die and connected to the bottom seal ring in the first seal ring region, the additional active region being configured to provide an electrical path to discharge charges formed in the interface during wafer stacking.

9. The package structure of claim 1, further comprising a delamination monitoring structure (DMS) configured to monitor delamination in the first seal ring region and the second seal ring region.

10. A method for fabricating a package structure, the method comprising:
fabricating a plurality of bottom dies, including a first bottom die, on a bottom wafer, the first bottom die comprising a first active region surrounded by a bottom seal ring;
fabricating a plurality of top dies, including a first top die, on a top wafer, the first top die comprising a second active region surrounded by a top seal ring;
forming a first bonding layer on a front surface of the bottom wafer and a first set of hybrid bonding metal pads (HBMPs) in the first bonding layer, wherein the first set of HBMPs are formed both in the first active region and aligned with the bottom seal ring;
forming a second bonding layer on a front surface of the top wafer and a second set of HBMPs in the second bonding layer, wherein the second set of HBMPs are formed both in the second active region and aligned with the top seal ring;
flipping the top wafer and bonding the flipped top wafer to the bottom wafer using hybrid bonding, wherein the first set of HBMPs and the second set of HBMPs are aligned and connected at an interface therebetween; and
performing a dicing process to isolate the package structure comprising the first top die bonded to the first bottom die.

11. The method of claim 10, further comprising forming an interconnect structure at a back surface of the top wafer.

12. The method of claim 10, further comprising forming an additional active region embedded in the bottom die, the additional active region electrically connected to the bottom seal ring.

13. The method of claim 12, further comprising forming a DTC region embedded in the top die.

14. The method of claim 10, further comprising forming a delamination monitoring structure (DMS) configured to monitor delamination in the bottom seal ring and the top seal ring.

15. A package structure comprising:
a bottom die comprising:
a first active region surrounded by a first seal ring region;
a first seal ring region comprising a bottom seal ring;
a first bonding layer disposed on a front side of the bottom die;
a first plurality of bottom hybrid bonding metal pads (HBMPs) disposed in the first bonding layer in the first seal ring region; and
a first plurality of bottom hybrid bonding via (HBVs) disposed in the first bonding layer and respectively connecting the bottom HBMPs and the bottom seal ring;
a top die comprising:
a second active region surrounded by a second seal ring region;
a second seal ring region comprising a top seal ring;
a second bonding layer disposed on a front side of the top die;
a first plurality of top HBMPs disposed in the second bonding layer in the second seal ring region, wherein the first plurality of top HBMPs are bonded to the first plurality of the bottom HBMPs, respectively; and
a first plurality top HBV disposed in the second bonding layer and respectively connecting the top HBMPs and the top seal ring; and
a delamination monitoring structure (DMS); and
wherein the bottom die and the top die are bonded through hybrid bonding between the first bonding layer and the second bonding layer at an interface therebetween such that the bottom seal ring and the top seal ring are vertically aligned, and wherein the bottom seal ring, the bottom HBV, the bottom HBMP, the top HBMP, the top HBV, and the top seal ring form a continuous seal ring, and wherein the DMS is configured to monitor delamination of the continuous seal ring.

16. The package structure of claim 15, wherein the DMS further comprises:
a first through-substrate via (TSV);
a second TSV;
a first routing connection;
a second routing connection; and
a portion of the continuous seal ring comprising a plurality of seal ring pillars, wherein the plurality of seal ring pillars comprise:
a starting continuous seal ring pillar;
an ending continuous seal ring pillar;
at least one seal ring pillar between the starting continuous seal ring pillar and the ending continuous seal ring pillar; and
a plurality of seal ring pillar interconnections that electrically connect the seal ring pillars to form an electrical path through the portion of the continuous seal ring, and
wherein the first TSV is electrically connected to the starting continuous seal ring pillar through the first routing connection, and wherein the second TSV is electrically connected to the ending continuous seal ring pillar through the second routing connection.

17. The package structure of claim 16, wherein the DMS further comprises:
a first monitoring structure metal pad disposed on a back side of the top die and connected to the first TSV; and
a second monitoring structure disposed on the back side of the top die and connected to the second TSV.

18. The package structure of claim 16, wherein the electrical path crosses the interface multiple times.

19. The package structure of claim 16, wherein the seal ring pillar interconnections are metal tracks extending horizontally.

20. The package structure of claim 16, wherein the first routing connection comprises a first metal track disposed in a first metal layer in the top die, and wherein the second routing connection comprises a second metal track disposed in the first metal layer.
